(19) United States
(12) Patent Application Publication
(10) Pub. No.: US 2015/0086050 A1
(43) Pub. Date: Mar. 26, 2015

(54) Chip with a Micro-Electromechanical Structure and Covering Element, and a Method for the Production of Same

(71) Applicant: Robert Bosch GmbH, Stuttgart (DE)

(72) Inventor: Ando Feyh, Palo Alto, CA (US)

(21) Appl. No.: 14/357,796

(22) PCT Filed: Sep. 27, 2012
(86) PCT No.: PCT/EP2012/069072

§ 371 Date: May 13, 2014

(30) Foreign Application Priority Data
Nov. 22, 2011 (DE) 10 2011 086765.1

(51) Int. Cl. B81B 7/00; H04R 17/00; B81C 1/00

(52) U.S. Cl. CPC B81B 7/0058; B81B 7/0077; B81C 1/00269; H04R 17/00; B81B 2201/0257
USPC 381/190; 257/416; 438/51

(57) ABSTRACT

A micro-electromechanical chip includes a substrate, a micro-electromechanical structure formed in the substrate, and a covering element that is positioned on a surface of the substrate and that is configured to protect the micro-electromechanical structure from at least one of outside contaminants and mechanical influences.

The invention relates to a chip comprising a microelectromechanical structure and a method for producing a chip comprising a microelectromechanical structure, in particular for microelectromechanical loudspeaker elements.

### PRIOR ART

Microelectromechanical loudspeakers (MEMS loudspeakers) are produced by forming microelectromechanical structures (MEMS structures) in a chip material. Such chips require a conventionally complex and cost-intensive packaging technology.

The document DE 10 2005 053 765 A1, for example, discloses an MEMS package comprising an MEMS chip and a control chip, which are applied on a carrier substrate and are encapsulated by means of a shielded cap.

### DISCLOSURE OF THE INVENTION

In accordance with one aspect, the present invention provides a microelectromechanical chip, comprising a substrate, a microelectromechanical structure formed in the substrate, and a covering element, which is arranged on a surface of the substrate and which protects the microelectromechanical structure from contaminants and/or mechanical influences from outside.

In accordance with a further aspect, the present invention provides a chip package comprising a microelectromechanical chip according to the invention, and a control chip, which is coupled to the microelectromechanical chip and is designed to drive the microelectromechanical chip.

In accordance with a further aspect, the present invention provides a method for producing a microelectromechanical chip, comprising the following steps: providing a multiplicity of microelectromechanical structures on a wafer, applying a covering element layer on the multiplicity of microelectromechanical structures on the wafer, and singulating the microelectromechanical structures for producing microelectromechanical chips having microelectromechanical structures which are covered by means of a covering element on a surface of the microelectromechanical chip.

### Advantages of the Invention

One concept of the present invention is to provide a chip comprising a microelectromechanical structure (MEMS chip), which chip has an acoustic window applied directly on a chip surface.

One advantage of the invention is that the production costs for such MEMS chips can be considerably reduced since the acoustic windows are applied to a wafer with MEMS chips in a single manufacturing step already at the wafer level and the chips can be singulated after the windows have been applied. In this case, one major advantage can be seen in the fact that the windows can protect the MEMS structures on the chips from contaminants resulting from the singulation process.

A further advantage of the invention is that the MEMS chip can be used in a chip package which does not have to be separately capped. As a result, firstly, the manufacturing costs are reduced; secondly, the structural size of the chip package is reduced. On account of the fact that no separate capping is necessary, chip packages comprising MEMS chips according to the invention can be designed as chip scale packages (CSP). As a result of the reduction of the structural size, moreover, the integration density is advantageously increased. This is particularly advantageous in the case of MEMS loudspeaker chips, which affords considerable advantages on account of the small structural height and the high integration density in miniaturized applications such as cellular phones, smartphones, tablet PCs, flat screens, loudspeakers integrated in wall coatings, or similar applications.

A further advantage is that the relative arrangement of control chip and MEMS chip on a substrate or a printed circuit board can be fashioned very flexibly, since the need for the additional capping is obviated.

In accordance with one embodiment, the microelectromechanical structure can comprise a microelectromechanical loudspeaker structure or a microelectromechanical microphone structure.

Particularly MEMS loudspeakers and MEMS microphones are well suited to the construction according to the invention since they cannot be protected from external influences by simple encapsulation by molding.

In accordance with a further embodiment, the covering element can be acoustically transparent. Preferably, the covering element can comprise a film, a metal grid, a plastic grid or a filter layer. This affords the possibility of protecting the MEMS structures, in particular MEMS loudspeaker structures, from mechanical influences, without crucially impairing the sound emission of the MEMS loudspeaker structures.

In accordance with a further embodiment, the covering element can be laminated or adhesively bonded on the substrate. This enables the MEMS chips to be manufactured cost-effectively and rapidly.

In accordance with a further embodiment, the covering element can form with the microelectromechanical structure a cavity within the substrate. By way of example, a resonator volume for emitting or picking up sound signals can be formed as a result.

In accordance with one embodiment of the chip package, an intermediate substrate can be provided, on the surface of which the microelectromechanical chip and the control chip are applied by means of soldering connections. In an alternative embodiment, the control chip can be embedded in a redistribution packaging chip, and the microelectromechanical chip can be applied on the redistribution packaging chip by means of soldering connections.

Preferably, the redistribution packaging chip can have at least one through contact via which the microelectromechanical chip is in electrical contact with soldering connections arranged soldering connections on that surface of the redistribution packaging chip which faces away from the microelectromechanical chip. As a result, the required chip area of the chip package, the so-called footprint, is advantageously reduced to the dimensions of the MEMS chip, since electrical connections do not have to be led past the redistribution packaging chip outside the chip area.

In accordance with one embodiment of the method, singulating can comprise sawing the wafer, incipiently sawing and breaking the wafer, or laser cutting the wafer. In this case, the advantage of the method is that contaminants which arise as a result of the singulating, such as, for example, sawing slurry or wafer fragments, are prevented by the covering elements from penetrating into the MEMS structures, such that the functionality and integrity thereof are maintained even in the course of the singulating process.

In accordance with one embodiment of the method, applying a covering element layer can comprise adhesively bonding or laminating the covering element layer on the wafer. This enables the wafer with the MEMS chips to be processed cost-effectively and rapidly.

Further features and advantages of embodiments of the invention will become apparent from the following description with reference to the accompanying drawings.

### BRIEF DESCRIPTION OF THE DRAWINGS

In the figures:

FIG. 1 shows a schematic illustration of a chip package with an MEMS chip in accordance with one embodiment of the invention;

FIG. 2 shows a schematic illustration of a chip package with an MEMS chip in accordance with a further embodiment of the invention;

FIG. 3 shows a schematic illustration of an MEMS chip in accordance with a further embodiment of the invention;

FIG. 4 shows a schematic illustration of an MEMS chip in accordance with a further embodiment of the invention; and

FIG. 5 shows a schematic illustration of a method for producing an MEMS chip in accordance with a further embodiment of the invention.

The configurations and developments described can, insofar as is expedient, be combined with one another in any desired manner. Further possible configurations, developments and implementations of the invention also encompass combinations—not explicitly mentioned—of features of the invention described above or below with regard to the exemplary embodiments.

The accompanying drawings are intended to convey a further understanding of the embodiments of the invention. They illustrate embodiments and in association with the description serve to elucidate principles and concepts of the invention. Other embodiments and many of the advantages mentioned are evident in view of the drawings. The elements in the drawings are not necessarily shown in a manner true to scale with respect to one another. In this case, identical reference signs designate identical or similarly acting components. Direction terminology used in the description such as “top”, “bottom”, “left”, “right”, “front”, “back” and the like serves merely for purposes of understanding and easier elucidation of elements in the drawings. This direction terminology should not be interpreted in a restrictive manner.

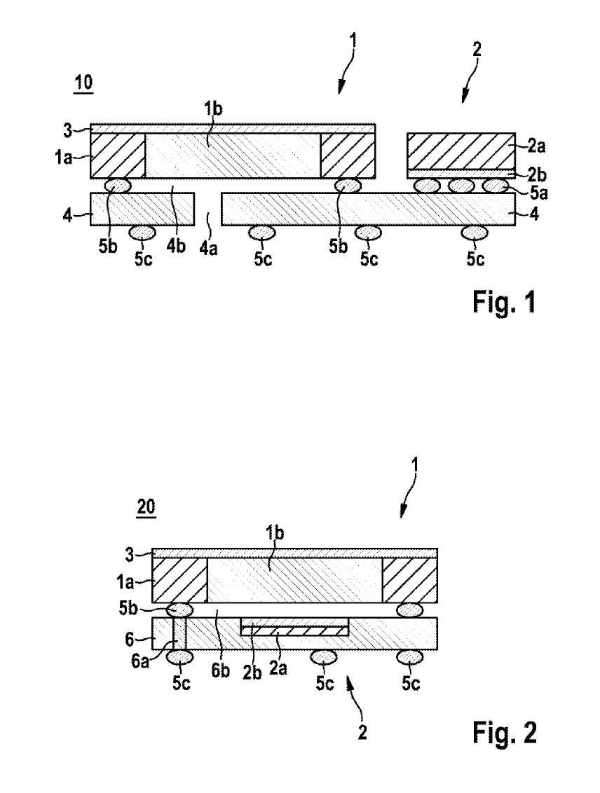

FIG. 1 shows a schematic illustration of a chip package 10 comprising a chip 1 having a microelectromechanical structure, hereinafter MEMS chip for short. The chip package 10 comprises an MEMS chip 1 which can have a microelectromechanical loudspeaker structure 1b, for example. In this case, the microelectromechanical loudspeaker structure 1b can be formed in a substrate 1a. The substrate 1a can comprise a silicon substrate, for example. The microelectromechanical loudspeaker structure 1b can have an array of individual microelectromechanical loudspeaker elements, for example. A covering element 3 can be applied on a surface on the MEMS chip 1.

The covering element 3 can comprise for example a film, for example composed of polyethylene terephthalate (Mylar®, Hostaphan®), a metal grid, a plastic grid or a filter layer. The covering element 3 can be acoustically transparent, for example, that is to say have a high transmissivity in relation to the propagation of sound waves. At the same time, the covering element 3 can be impermeable to contaminants such as dust, fluids or other particles. The covering element 3 can be applied on the MEMS chip 1 for example by adhesive bonding, fusion, lamination or a similar connecting process with or without a thermal step.

The chip package 10 can furthermore comprise a control chip 2, for example an ASIC chip, an FPGA chip or CPLD chip. The control chip 2 can be coupled to the MEMS chip 1 and be designed to generate a drive signal for the MEMS chip 1. By way of example, the control chip 2 can be designed to drive the microelectromechanical loudspeaker structure 1b of the MEMS chip 1 for generating sound signals. In this case, the control chip 2 can have a chip body 2a, to which an integrated circuit 2b is applied on a surface. The control chip 2 and the MEMS chip 1 can be applied for example in each case in a flip-chip arrangement on a carrier substrate 4. The carrier substrate 4 can be for example an intermediate substrate layer, a so-called interposer. The control chip 2 and the MEMS chip 1 can be applied on the carrier substrate 4 by means of solder bumps or soldering connections 5a and 5b, respectively. The number of soldering connections 5a and 5b in FIG. 1 is merely by way of example; any other number of soldering connections is likewise possible in this case.

The carrier substrate 4 can have, for its part, by means of solder bumps or soldering connections 5c on the side facing away from the MEMS chip 1 and the control chip 2, which are designed to apply the carrier substrate 4 on a printed circuit board (not shown), for example. The number of soldering connections 5c in FIG. 1 is merely by way of example; any other number of soldering connections is likewise possible in this case. The carrier substrate 4 can have for example an opening, such as a through hole 4a, for example. The through hole 4a can be formed for example below the chip area of the MEMS chip 1, such that the cavity 4b below the MEMS chip 1 between MEMS chip 1 and carrier substrate 4 is connected to the outside world. If the MEMS chip 1 has a microelectromechanical loudspeaker structure 1b, the through hole 4a can serve as an acoustic port downward.

FIG. 2 shows a schematic illustration of a further chip package 20 comprising an MEMS chip 1. The chip package 20 differs from the chip package 10 in that the MEMS chip 1 and the control chip 2 are arranged in a stacked arrangement one above the other. For this purpose, the control chip 2 can be configured in a cutout of a redistribution packaging chip 6. The redistribution packaging chip 6 can comprise molding material or plastic material, for example. The redistribution packaging chip 6 can serve as a reconfigured wafer, for example, into which the control chip 2 is embedded (mWLP, “molded wafer level package”). The control chip 2, which has a smaller chip area than the MEMS chip 1, for example, can in this case be arranged completely below the chip area of the MEMS chip 1, such that the redistribution packaging chip 6 has the same chip area as the MEMS chip 1. In this way, the entire chip package 20 cannot have more area than the MEMS chip 1 itself.

The redistribution packaging chip 6 can have through contacts 6a, for example, via which the MEMS chip 1 with soldering connections 5b is in electrical contact with the underside of the redistribution packaging chip 6, for example with soldering connections 5c on the underside of the redistribution packaging chip 6. The control chip 2 can be embedded in the redistribution packaging chip 6 in such a way that the surface with the integrated circuit 2a faces toward the MEMS chip 1. In particular, the terminals of the control chip 2 can be arranged in a fan-out structure on the redistribution wiring chip 6. A cavity 6b can be arranged between the redistribution packaging chip 6 and the MEMS chip 1, which cavity can serve as a resonator cavity for example for MEMS chips 1 comprising microelectromechanical loudspeaker structures 1b.

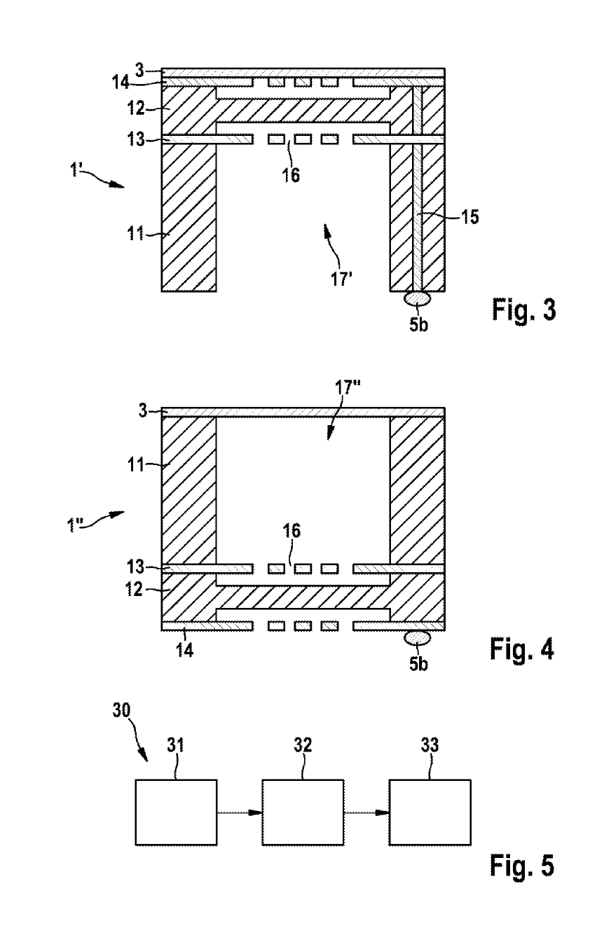

FIG. 3 shows a schematic illustration for one exemplary embodiment of an MEMS chip 1′. The MEMS chip 1′ can be an MEMS loudspeaker chip, for example. The MEMS chip 1′ has a chip body 11, which forms a cavity 17′ accessible from the underside of the MEMS chip 1′. In the cavity 17′, MEMS structure elements 16 can in each case be formed in MEMS structure layers 13 and 14. The MEMS structure elements 16 here can be for example membrane elements of a microelectromechanical loudspeaker structure 1b, as shown in FIG. 1. By way of example, an intermediate layer 12 of the chip body material can be formed between the MEMS structure elements 16. The chip body 11 can comprise silicon, for example.

The MEMS chip 1′ furthermore has a covering element 3 that has been described thoroughly in connection with FIG. 1. In this case, the covering element 3 can be applied on that surface of the MEMS chip 1′ which faces away from the cavity 17′. The covering element 3 can form an acoustic window, for example, which keeps contaminants away from the MEMS chip 1′ and in particular the MEMS structure elements 16, but at the same time can transmit toward the outside sound signals generated with the aid of the MEMS structure elements 16 in the MEMS chip 1′. In this case, it can also be possible for covering elements 3 to be fitted on both chip surfaces of the MEMS chip 1′.

By way of example, through contacts 15 can be formed through the chip body 11, said through contacts connecting the active layers 13 and 14 in each case to soldering connections 5b on the underside of the MEMS chip 11, such that the MEMS chip 11 can be applied and electrically contact-connected on a carrier substrate.

FIG. 4 shows a schematic illustration for a further exemplary embodiment of an MEMS chip 1″. The MEMS chip 1″ in FIG. 4 differs from the MEMS chip 1′ in FIG. 3 to the effect that the covering element 3 is applied on that surface of the MEMS chip 1″ which faces away from the MEMS structure elements 16. This gives rise to a cavity 17″ in the interior of the chip body 11, which is protected against contaminants from outside. The MEMS chip 1″ affords the advantage that no through contacts are required, rather the soldering connections 5b can be linked directly to the active layers 14 and, if appropriate, 13.

The MEMS chip 1″ can be applied as MEMS chip 1, as illustrated in FIG. 3, on a redistribution packaging chip 6 using a mechanical spacer layer. By means of the spacer layer, for an MEMS loudspeaker chip, for example, it is possible to provide a required back volume between MEMS chip 1″ and redistribution packaging chip 6. The spacer layer can for example comprise silicon or be a PCB layer (“printed circuit board”). The back volume can be realized for example by means of a cutout and/or through holes in the spacer layer.

In this case, it can also be possible for covering elements 3 to be fitted on both chip surfaces of the MEMS chip 1″.

FIG. 5 shows a schematic illustration of a method 30 for producing an MEMS chip, in particular one of the MEMS chips 1, 1′ or 1″ as shown in FIGS. 1 to 4. A first step 31 involves providing a multiplicity of MEMS structures on a wafer. A second step 32 involves applying a covering element layer on the multiplicity of MEMS structures on the wafer. This can be done for example by means of an acoustically transparent covering element 3 being laminated thereon or adhesively bonded thereon, as described in connection with FIG. 1. The covering element layer can be a continuous layer composed of the material constituting the covering elements 3. Alternatively, it can also be possible to apply the covering elements 3 individually to the multiplicity of MEMS structures on the wafer.

A third step 33 involves singulating the MEMS structures in order to produce MEMS chips comprising MEMS structures which are covered by means of a covering element on a surface of the MEMS chip. The singulating can comprise for example sawing the wafer, incipiently sawing and breaking the wafer or laser cutting the wafer. For the laser cutting, for example by means of laser action, one or a plurality of predetermined breaking locations can be produced in the wafer, at which locations the wafer can then be broken.

The method 30 firstly affords the advantage that the covering elements of the MEMS chips can be applied on a wafer in one individual manufacturing step, and do not have to be applied individually on MEMS chips. Secondly, the covering elements protect the MEMS structures against contaminants arising in step 33, such as sawing slurry, wafer fragments, cooling liquids, or similar materials, which could impair the functionality and integrity of the MEMS structures.

1. A microelectromechanical chip, comprising:
a substrate;
a microelectromechanical structure formed in the substrate; and
a covering element disposed on a surface of the substrate and configured to protect the microelectromechanical structure from at least one of contaminants and mechanical influences from outside.

2. The microelectromechanical chip as claimed in claim 1, wherein the microelectromechanical structure comprises a microelectromechanical loudspeaker structure or a microelectromechanical microphone structure.

3. The microelectromechanical chip as claimed in claim 1, wherein the covering element is acoustically transparent.

4. The microelectromechanical chip as claimed in claim 3, wherein the covering element comprises a film, a metal grid, a plastic grid, or a filter layer.

5. The microelectromechanical chip as claimed in claim 1, wherein the covering element is laminated or adhesively bonded on the substrate.

6. The microelectromechanical chip as claimed in claim 1, wherein the covering element forms, with the microelectromechanical structure, a cavity within the substrate.

7. A chip package, comprising:
a microelectromechanical chip that includes
a substrate;
a microelectromechanical structure formed in the substrate; and
a covering element positioned on a surface of the substrate and configured to protect the microelectromechanical structure from at least one of contaminants and mechanical influences from outside; and
a control chip coupled to the microelectromechanical chip and configured to drive the microelectromechanical chip.

8. The chip package as claimed in claim 7, further comprising:
an intermediate substrate wherein the microelectromechanical chip and the control chip are disposed on a surface of the intermediate substrate via soldering connections.

9. The chip package as claimed in claim 7;
wherein the control chip is embedded in a redistribution packaging chip; and
wherein the microelectromechanical chip is disposed on the redistribution packaging chip via first soldering connections.

10. The chip package as claimed in claim 9, wherein the redistribution packaging chip has at least one through contact via which the microelectromechanical chip is in electrical contact with second soldering connections located on a surface of the redistribution packaging chip which faces away from the microelectromechanical chip.

11. A method for producing a microelectromechanical chip, comprising:
providing a multiplicity of microelectromechanical structures on a wafer;
applying a covering element layer on the multiplicity of microelectromechanical structures on the wafer; and
singulating the multiplicity of microelectromechanical structures into a plurality of microelectromechanical chips respectively having a microelectromechanical structure covered by a covering element, from the covering element layer, that is disposed on a surface of each of the plurality of microelectromechanical chips.

12. The method as claimed in claim 11, wherein the singulating comprises sawing the wafer, incipiently sawing and breaking the wafer, or laser cutting the wafer.

13. The method as claimed in claim 11, wherein applying the covering element layer comprises adhesively bonding or laminating the covering element layer on the wafer.
